(19) United States
(12) Patent Application Publication
(10) Pub. No.: US 2026/0329078 A1
(43) Pub. Date: Oct. 22, 2026

(54) GAZE TRACKING SYSTEM FOR WEARABLE ELECTRONIC DISPLAY DEVICE

(71) Applicant: Apple Inc., Cupertino, CA (US)

(72) Inventors: Nivay Anandarajah, San Jose, CA (US); Darshan R Kasar, Redwood City, CA (US); Guy Lederman, Ramat Gan (IL); Katya Gotlib, Pethah Tikva (IL)

(21) Appl. No.: 19/327,598

(22) Filed: Sep. 12, 2025

Related U.S. Application Data
(60) Provisional application No. 63/792,756, filed on Apr. 22, 2025.

(51) Int. Cl. G02B 27/00; G02B 7/00; G02B 27/01; G03B 15/05; H05K 1/14

(52) U.S. Cl. CPC G02B 27/0093; G02B 7/002; G02B 27/0172; G02B 27/0176; G03B 15/05; H05K 1/147; G02B 2027/0138; G02B 2027/0178; G03B 2215/0567; H05K 2201/10106; H05K 2201/10121; H05K 2201/10371; H05K 2201/10378

(57) ABSTRACT

A wearable electronic display device can include a structural frame including a nosepiece. The nosepiece can include a housing and a gaze tracking system. The gaze tracking system can be disposed in the housing. The gaze tracking system can include a printed circuit board, a camera, an illuminator, a flexible circuit, and a motion sensor. The printed circuit board can include a first side and a second side opposite the first side. The camera can be coupled to the first side. The illuminator can be coupled to the first side and can be electrically coupled to the camera. The flexible circuit can be coupled to the second side. The motion sensor can be coupled to the first side or to the flexible circuit. The motion sensor can be electrically coupled to the camera and to the illuminator.

### CROSS-REFERENCE TO RELATED APPLICATIONS

This application claims the benefit of U.S. Provisional Application No. 63/792,756, filed 22 Apr. 2025, entitled “GAZE TRACKING SYSTEM FOR WEARABLE ELECTRONIC DISPLAY DEVICES,” the entire disclosure of which is hereby incorporated by reference.

### FIELD

The present disclosure relates generally to wearable electronic display devices. More particularly, the present embodiments relate to gaze tracking devices and systems.

### BACKGROUND

Eye-tracking is a process for detecting the eye movement or the eye-gaze direction of an individual. Various eye-tracking technologies have been developed for use in a variety of applications, such as vision research, human computer interfaces, telesurgery, advertising research, psychology, and visual communication. Wearable devices and systems benefit from eye-tracking information and function as an advantageous platform for eye-tracking because eye measurements collected from a platform close to one or both eyes reduce measurement errors generated by head movements and other sources. Additionally, eye-tracking can form an important element for receiving input from users and for ensuring accurate content to the user. Current wearable systems that incorporate eye-tracking systems are often bulky, difficult to manufacture, aesthetically displeasing, and expensive due to the size of the gaze tracking system. These systems can also create obtrusions to the vision of the user and/or require thick frames or other design modifications affecting otherwise aesthetically pleasing, sleek structural frames for head-mountable devices.

### SUMMARY

In at least one example of the present disclosure, a wearable electronic display device can include a structural frame including a nosepiece. The nosepiece can include a housing and a gaze tracking system. The gaze tracking system can be disposed in the housing. The gaze tracking system can include a printed circuit board, a camera, an illuminator, a flexible circuit, and a motion sensor. The printed circuit board can include a first side and a second side opposite the first side. The camera can be coupled to the first side. The illuminator can be coupled to the first side and electrically coupled to the camera. The flexible circuit can be electrically coupled to the second side. The motion sensor can be coupled to the first side or to the flexible circuit. The motion sensor can be electrically coupled to the camera and to the illuminator.

In some examples, the camera can include a radial angle of view. In some examples, the illuminator can include a radial angle of illumination. In some examples, the radial angle of view and the radial angle of illumination can define an intersection. In some examples, the housing can be disposed between the illuminator and the intersection. In some examples, the wearable electronic display device can further include an interposer electrically connected to the camera. In some examples, the wearable electronic display device can further include an interposer electrically connected to the camera. In some examples, the interposer can be coupled to at least one of the second side or the flexible circuit. In some examples, the gaze tracking system can further include a shield can coupled to at least one of the first side, the second side, or the flexible circuit. In some examples, the illuminator can include an electromagnetic interference shield. In some examples, the illuminator can include a light seal. In some examples, the flexible circuit is electrically coupled to the second side through at least one of a hot bar connection or a board-to-board connection. In at least some examples, the printed circuit board can include a rigid printed circuit board. In at least some examples, the nosepiece can further include an internal cavity positioned adjacent to the housing. In some examples, the flexible circuit can be cantilevered into the internal cavity.

In at least one example a wearable electronic display device can include a structural frame and a motion detector. The structural frame can define a housing. The housing can include a window and a camera system. The camera system can be disposed in the housing and can include an electronic flex, a camera, an illuminator, and a stiffener. The camera can be coupled to the electronic flex and configured to project a first light cone. The illuminator can be coupled to the camera via the electronic flex. The illuminator can be configured to project a second slight cone. The second light cone and the first light cone can define an intersection, and the window can be disposed between the camera and the intersection. The stiffener can be coupled to the electronic flex and can be cantilevered into the structural frame. The motion detector can be coupled to at least one of the electronic flex or the stiffener. The motion detector can be electrically coupled to the camera and the illuminator.

In some examples, the camera system can include a thickness of less than five (5) millimeters. In some examples, the camera system can include a thickness of less than three (3) millimeters. In some examples, the illuminator can include a light-emitting diode. In some examples, the illuminator can include an infrared flood illuminator.

In at least one example of the present disclosure, a viewing frame of a wearable electronic display device can include a nosepiece defining a housing. The housing can include a nose bridge and an inward facing camera system. The nose bridge can be configured to rest on a nose of a user. The inward facing camera system can be disposed in an internal cavity of the housing. The inward facing camera system can include a first circuit, a camera, an illuminator, a second circuit, a flexible printed circuit, and a gyroscope. The first circuit can have a printed circuit board (PCB). The camera can be electrically coupled to the first circuit via the PCB. The illuminator can be electrically coupled to the first circuit via the PCB. The second circuit can be disposed in the nose bridge. The flexible printed circuit can be coupled to the PCB and can electrically couple the first circuit to the second circuit. The gyroscope can be coupled to the PCB or the flexible printed circuit and can be electrically coupled to the first circuit.

In some examples, the gyroscope can include a pin connector configured to couple to at least one of the PCB or the flexible printed circuit. In some examples, the gyroscope can be rigidly coupled to the camera. In some examples, the gyroscope can be positioned in line with at least one of the camera or the illuminator. In some examples, the gyroscope is positioned between the nose bridge and both the camera and the illuminator, or the camera and the illuminator can be both positioned between the gyroscope and the nose bridge.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 shows a back perspective view of a wearable electronic display device with a gaze tracking system;

FIG. 2A shows a cross-sectional view of a wearable electronic display device with a gaze tracking system;

FIG. 2B shows an enlarged schematic view of the gaze tracking system of FIG. 2A;

FIG. 3 shows a cross-sectional schematic view of a camera system;

FIG. 4 shows a cross-sectional schematic view of a camera system;

FIG. 5A shows a cross-sectional schematic view of a camera system;

FIG. 5B shows a cross-sectional schematic view of a camera system;

FIG. 6A shows an exploded example of a cross-sectional view of a camera system;

FIG. 6B shows an example of a schematic cross-sectional view of a camera system;

FIG. 7 shows an enlarged view of a nosepiece of a wearable electronic display device with two gaze tracking systems;

FIG. 8A shows a method of installing a gaze tracking system within a wearable electronic display device; and

FIG. 8B shows a method of installing a gaze tracking system within a wearable electronic display device.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The following disclosure relates to a gaze tracking system or an eye-tracking system that can be included within any type of wearable or head-mountable electronic device such as a virtual reality device, mixed reality device, smart glasses device, smart eyeglass system, or an optical device that is wearable similar to a pair of goggles or eyeglasses. Eye-tracking can include capturing and/or measuring either the point of gaze, where the user that has donned the wearable electronic device is looking, or the motion of one or both of the user's eyes relative to the head. The retina of the eye includes an area of dense nerves and high-visual acuity called the fovea. The lens of the eye focuses light on the fovea, and muscles move the eyes to direct the lens and the fovea where the user wants to look. Current eye-tracking systems can be bulky and can require a large amount of space when included within a wearable electronic device. This can take away space available for other components of the wearable electronic device, such as the display.

Additionally, the eye tracking system must be in line with or nearly in line with the front of the user's eyes in order to track the user's gaze. Thus, the gaze tracking system can take up critical display space that is within the user's normal field of vision when the user is looking straight ahead. This can lead to an obstructed view of the graphics displayed on the wearable electronic device or of the surroundings for wearable electronic devices with transparent lenses such as eyeglasses. The display can be distorted or otherwise less aesthetically pleasing by including gaze tracking components, reducing the effect of VR/MR devices or otherwise producing an otherwise nearly seamless display or field of view. Even if the eye-tracking system is included at a less obtrusive angle, the resulting structure can take away from the otherwise sleek frame design of the eyewear device, requiring a bulkier frame to fit the gaze tracking device or creating an aesthetically displeasing mound within the frame, such as on the nose bridge of the wearable electronic device.

Wearable devices described in the present disclosure include gaze-tracking systems and components that are easy to manufacture, lightweight, and compact such that they are less-noticeable and less obtrusive to the user's vision. In some examples, a wearable electronic device can include a structural frame including a nosepiece that can be configured to rest on the nose of a user, such as a head-mountable device like a virtual reality device, a mixed reality device, eyeglasses, sunglasses, goggles or a similar ocular device designed to be worn on a user's head. In some examples, the nosepiece can include a housing with a gaze tracking system disposed within it. In some examples, the gaze tracking system can be configured to be compact, including all of the necessary components in a simple configuration on one or both of a printed circuit board and a flexible circuit so that the components are electrically coupled and compactly fit within the housing, while also being simple and cost effective to manufacture and install into a variety of different structural frame sizes and shapes. In some examples, the camera and illuminator can be coupled to a first side of the printed circuit board and a flexible circuit can be coupled to the second side of the printed circuit board. In some examples, a motion sensor can be coupled to the second side of the printed circuit board or it can be coupled to the flexible circuit, ensuring that all of the components of the gaze tracking system are electrically coupled while minimizing the dimensions of the gaze tracking system in the x-, y-, and z-directions, or the length, height, and width dimensions.

In some examples, a wearable electronic display device can include a structural frame defining a housing. In some examples, the housing can include a window and a camera system, with the window allowing the camera visual access to the user's eye(s) when the user has donned the wearable electronic display device. In some examples the window can be around 0.3 millimeters thick. In some examples, the camera system can include an electronic flex electrically coupling the camera and the illuminator. In some examples, the camera can be configured to project a first light cone, that light cone including a radius in which the camera can sense and capture images of the user's eye.

Similarly, in some examples, the illuminator can be configured to project a second light cone, illuminating the user's eye within the radius of the projected light cone. In some examples, the radius of the first light cone is configured to overlap with the radius of the second light cone outside of the window so that the eye is sufficiently illuminated for the camera to detect and capture images of the eye. However, in some examples, the camera and the illuminator can be positioned within the housing of the structural frame to be in close proximity to the window, allowing the camera and illuminator to be close together while still preventing the radius of the first light cone and the second light cone from overlapping before the window. Overlapping of the light cones before the window can create light interference within the housing such as reflections which can cause the camera to stop working or to work less effectively. In some examples, the camera system can also include a stiffener that can be coupled to the electronic flex, the stiffener can be rigid at least in part to securely position the camera system within the frame that the stiffener is cantilevered into so that the camera and illuminator can securely be placed as close in proximity to the window as possible with little movement of the camera system after its installation into the wearable electronic display device.

In some examples, a viewing frame of the wearable electronic display device can include a nosepiece defining a housing. In some examples, the nosepiece can include a nose bridge configured to rest on a nose of the user and an inward facing camera system. In some examples, the inward facing camera system can have two circuits, one within an internal cavity of the housing with a camera, an illuminator and a gyroscope, and a second circuit within the nose bridge of the wearable electronic display device. In some examples, these two circuits can be electrically connected via a flexible printed circuit. In some examples, the first circuit can also include a printed circuit board electrically coupling the components of the first circuit, the camera, illuminator, gyroscope, and others, with the flexible printed circuit and any components electrically coupled thereto. In some examples, a gyroscope can be coupled to the printed circuit board or the flexible circuit and can be configured to reposition one or both of the camera or the illuminator so the inward facing camera system is in line with the eye of the user, despite users potentially having a variety of different face sizes and shapes, or with a feature of the eye to enable the inward camera system to effectively track the user's gaze.

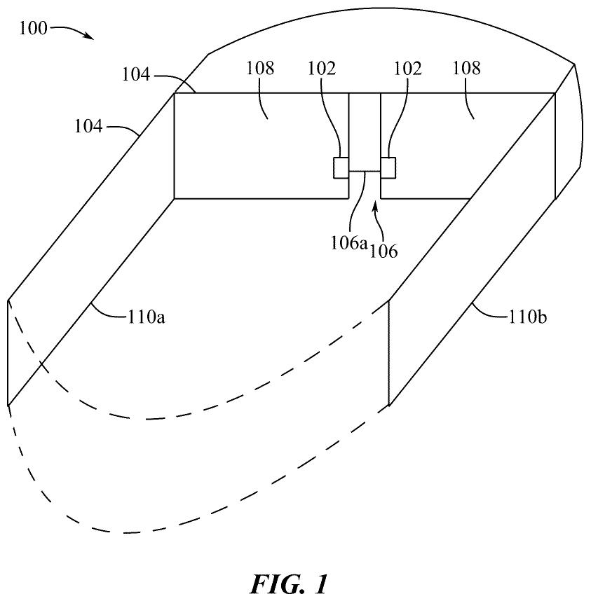

These and other embodiments are discussed below with reference to FIG. 1-8B. However, those skilled in the art will readily appreciate that the detailed description given herein with respect to these figures is for explanatory purposes only and should not be construed as limiting. Furthermore, as used herein, a system, a method, an article, a component, a feature, or a sub-feature including at least one of a first option, a second option, or a third option should be understood as referring to a system, a method, an article, a component, a feature, or a sub-feature that can include one of each listed option (e.g., only one of the first option, only one of the second option, or only one of the third option), multiple of a single listed option (e.g., two or more of the first option), two options simultaneously (e.g., one of the first option and one of the second option), or combination thereof (e.g., two of the first option and one of the second option).

FIG. 1 shows a back view of a wearable electronic display device 100 with a gaze tracking system 102. The wearable electronic display device 100 can be a head-mounted device, resting on the face of a user and being supported by the head, nose, ears, and/or other body part of the user's face. In some examples, the wearable electronic display device 100 can provide a user with a visual or auditory experience. In some examples, the wearable electronic display device 100 can be an augmented reality device or a virtual reality device. In some examples, the wearable electronic device 100 can be a type of smart glasses, smart sunglasses, or other eyeglasses. In some examples, the optical device 100 can be configured as a helmet. The wearable electronic display device 100 can include a structural frame 104. The structural frame 104 can include a nosepiece 106 with a nose bridge 106a which can be configured to rest on the nose of a user or otherwise press against the nasal area of the user to help keep the wearable electronic display device 100 in position on the user's face. In some examples, the nosepiece can include a nose pad and the gaze tracking system 102 can in some examples be included in the nose pad. The wearable electronic display device can include a display 108. The display 108 can be at least partially transparent, allowing a user to see through the display 108. The display can overlay information, graphics, video, or other media over the field of view of a user. In some examples, the display 108 can be a screen that at least partially fills the field of view of a user. The screen can be an LED screen, an OLED screen, a projection, an LCD screen, or another type of screen.

The wearable electronic display device 100 can also include securement arms 110a-b extending distally from the display 108. In some examples, the securement arms 110a-b can rest on the ears of a user and/or engage a side of a user's head and can at least partially support the wearable electronic display device 100. Not shown in this figure, but the wearable electronic display device can alternatively include a retention band, or another means of retaining the wearable electronic display device 100 on the user's head by resting upon the user's ears or otherwise engaging with the side of the user's head. In some examples, the securement arms 110a-b or retention band can be foldably attached to the structural frame 104. In some examples, foldable securement arms 110a-b or the retention band can collapse inward toward the display 108, increasing portability and decreasing the stowed size of the wearable electronic display device 100. In other examples, the securement arms 110a-b or retention band can be removably secured to the display 108.

In some examples, the structural frame 104 of the wearable electronic device 100 can be manufactured from polymers composites or metals. In some examples, the structural frame 104 can be injection molded, cast, machined, or welded to produce a unitary piece. In some examples, the structural frame 104 can be of any geometry including one or more straight or curved edges. In some examples, the structural frame 104 can also be any geometry, particularly around the display 108 including rectangular, cylindrical, or of a tapered geometry. In some examples, the structural frame 104 can mirror the geometry of the display 108. In other examples, the structural frame 104 can differ from the geometry of the display 108.

In some examples, the display 108 can alternatively include lenses. In some examples, the lenses can be replaceable or interchangeable to correspond to a different user's prescription or to correspond to the activity of the user. Alternatively, the structural frame 104 can be assembled according to measurements provided to a supplier and further customized by interchangement portions, such as the inclusion or modification of nose pads as required by the user. Multiple design solutions are envisioned for integration of the gaze tracking system 102 into wearable electronic display devices 100 such as goggles, masks, sunglasses, HMDs, and other suitable embodiments.

Any of the features, components, and/or parts, including the arrangements and configurations thereof shown in FIG. 1 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 1.

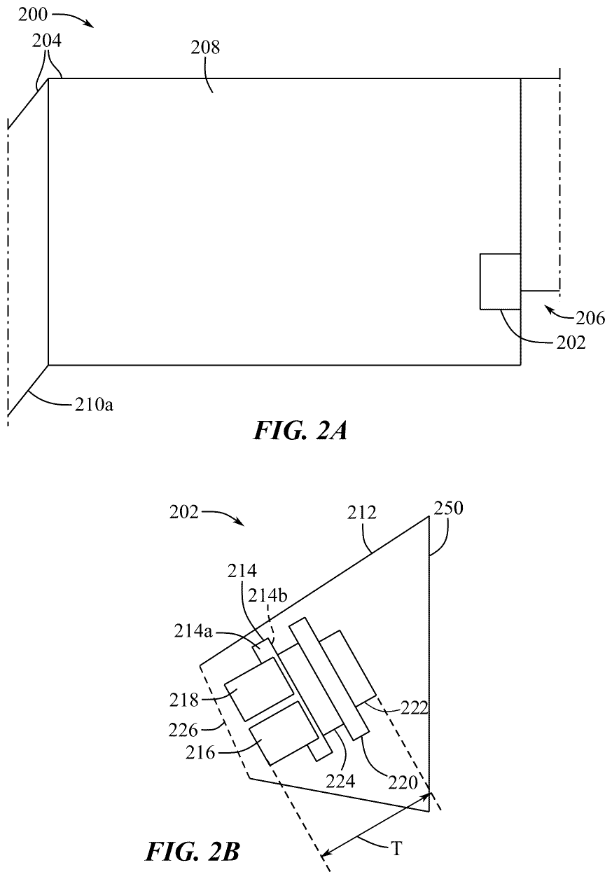

FIG. 2A shows an example of a cross-sectional view of a wearable electronic display device 200 with a gaze tracking system 202. The wearable electronic display device 200 shown in FIG. 2A can be substantially similar to the wearable electronic display device 100 shown in FIG. 1, including some or all of the features of the wearable electronic display device 100 such as a gaze tracking system 202, a structural frame 204, a nosepiece 206, a display 208, and securement arm(s) 210a or a retention band. In some examples, the gaze tracking system 202 can be contained within a housing 212 of the structural frame, such as a housing 212 located within the nosepiece 206 of the wearable electronic device 200. In some examples, the nosepiece 206 can connect the lenses or portions of the display 208. In other examples, the display 208 can overlap with the nosepiece 206 allowing the display 208 or lenses to cover the nosepiece 206 configured to rest upon the nose of the user or otherwise press on the nasal region of the user to secure the wearable electronic display device's 200 position on the user's face. In other examples, the gaze tracking system 202 can be mounted to the structural frame 204 towards the face of the user. In some examples, the gaze tracking system 202 can be mounted on and/or disposed within the nosepiece 206. In other examples, the gaze tracking system 202 can be mounted on and/or disposed within structural frame surrounding the lenses or display 208. In some examples, the gaze tracking system 202 can be positioned having an unobstructed view of the eye of the user of the wearable electronic display device 200. In some examples, the positioning of the gaze-tracking system 202 can provide a good angle to the parts of the eye required for tracking without obstruction from the eye lashes or other impediments.

FIG. 2B shows an example of an enlarged view of the gaze tracking system 202 of FIG. 2A. In some examples, the gaze tracking system 202 can include a printed circuit board 214, a camera 216, an illuminator 218, a flexible circuit 220, and a motion sensor 222. In some examples, the printed circuit board 214 can include a first side 214a and a second side 214b, the second side 214b opposite the first side 214a. In some examples, the printed circuit board can include components coupled to either side 214a-b and can electrically couple the various components on it together. In some examples, the printed circuit board 214 can be rigid or can be made with a rigid substrate material. A “rigid” component or material can be one intended to maintain its shape or form for proper functioning. “Rigid” components or materials, as described herein, are not intended to bend, deform, change shape, or change form as part of the intended functionality of the component or material. For example, the printed circuit board 214 can be designed to be rigid, resist deformation, and otherwise include of material that resists altering its manufactured shape during normal use. In some examples, the printed circuit board 214 can include fiberglass, epoxy, metals, solder mask and other similar materials. In some examples, a camera 216 can be coupled to the first side 214a of the printed circuit board 214. In some examples, an illuminator 218 can be coupled to the first side 214a and electrically coupled to the camera 216. In some examples, a flexible circuit 220 can be coupled to the second side 214b. In some examples, a motion sensor can be coupled to the second side 214b. In other examples, the motion sensor 222 can be coupled to the flexible circuit 220. In some examples the motion sensor can detect and/or measure one or more of angular velocity, rotational speed, the orientation of rotation, or other similar motions.

In some examples, the components within the gaze tracking system 202 can be stacked together and can generally be in line with each other as shown in FIG. 2B. For example, as shown in FIG. 2B, the motion sensor 222, the flexible circuit 220, the other component 224, the printed circuit board 214, and the layer including both the camera 216 and illuminator 218 all generally centered around the same central axis parallel to the gaze tracking system's 202 thickness T, making them look in line with each other. In other examples, not shown in FIG. 2B, the components such as the camera 216, the illuminator 218, the motion sensor 222 or other electronic components not shown in FIG. 2B can be staggered, resembling a stair-like configuration or other configuration including the components in the gaze tracking system 202 not generally centered around the same central axis parallel to the gaze tracking system's 202 thickness T. In other examples, the staggered configuration includes the components of the gaze tracking system 202 are not in line or positioned symmetrically on the printed circuit board 214 and/or the flexible circuit 220. In some examples, the staggered position within the housing 212 may save space and reduce the thickness of the gaze tracking system, T, depending on the geometrical shape of the housing 212. For example, the motion sensor 222 can be positioned between to the nosepiece 206 of the wearable electronic display device 200 and both the camera 216 and the illuminator 218. Other components, 224, can be included in the gaze tracking system 202. These other components, 224 can include a shield can, or other specific electrical or mechanical components. In some examples, the camera 216 and/or the illuminator 218 can include an electromagnetic interference shield designed to shield the camera 216 and/or the illuminator 218 by blocking or absorbing at least one of an electromagnetic interference or an electromagnetic field created by one or more of the camera 216, the illuminator 218, or one or more other electronic components within the gaze tracking system 202.

These other components, 224 can also be placed in the stacked configuration to be in line with the other components or staggered to save space within the geometry of the housing 212. In FIG. 2B, one or more other components 224 is shown staggered from the camera 216, illuminator 218, and motion sensor 222 in the gaze tracking system 202 stack, and although it is shown coupled to the flexible circuit 220, it is not limited to that configuration or to only one configuration. For example, the one or more other components 224 can be positioned and coupled to the second side 214b of the printed circuit board 214 and to the flexible circuit 220, or it can be coupled to the first side 214a, just the second side 214b, or to either side of just the flexible circuit 220. In some examples, the motion sensor 222 can be electrically coupled to the camera 216 and to the illuminator 218. Although the motion sensor 222 is shown coupled to one side of the flexible circuit 220 in FIG. 2B, this configuration is not limiting. In some examples, the motion sensor 222 can also be coupled to the other side of the flexible circuit 220, the other side of the flexible circuit 220 and the second side 214b, to the second side 214b, or to the first side 214a.

FIG. 2 shows a thickness T representing the measurement described as the thickness of the gaze tracking system 202. Although all of the dimensions in each direction, i.e. height, width, and thickness T, are relevant and are minimized for compact design purposes, the thickness T can determine how far out the gaze tracking system 202 is raised relative to the structural frame 204 and/or relative to a display coupled to the structural frame 204. In some examples, the thickness T of the gaze tracking system 202 can be measured from the top surface of the component closest to the window 226, for example from the camera 216 and/or the illuminator 218, to the surface nearest the rear wall 250 of the component closest to the rear wall 250. For example, in FIG. 2., the thickness T is measured from the top surface of the illuminator 218 to the top or bottom surface of the motion sensor 222 (depending on the orientation of the motion sensor 222). In some examples, the gaze tracking system 202 or the camera system comprises a thickness of less than five (5) millimeters. In some examples, the gaze tracking system 202 or the camera system comprises a thickness of less than three (3) millimeters. The size and shape of all of the components within the gaze tracking system 202, such as the camera 216, illuminator 218, motion sensor 222, printed circuit board 214, etc. are not meant to reflect their actual sizes (heights, widths, thicknesses) or shapes as each components'sizes and shapes can widely vary and this disclosure is not meant to limit the size or shape of any of the components to the sizes or shapes shown in the figures.

In some examples, the camera 216 and illuminator 218 can be positioned near a window 226 disposed in the housing 212. In some examples, the housing 212 is volcano or conically-shaped, including a mound that is cylindrical or rectangular and is either disposed within the structural frame 204 or protruding from the structural frame 204 toward the eye of the user. In some examples, although the housing 212 shown in FIG. 2B has a rear wall 250 shown opposite the window 226, a rear wall 250 does not need to be included, as the housing 212 can be disposed within the structural frame 204. Similarly, although the camera 216 and the illuminator 218 appear to be pointed downward in FIG. 2B, this is also not limiting. In some examples, the camera 216 and the illuminator 218 can be positioned differently or the stack of components making up the gaze tracking system 202 can be repositioned, turned, face straight forward, face upward, downward, inward, outward, or be moveable by the motion sensor 222. Similarly, in some examples, the geometry of the housing 212 can be any geometry and the components of the gaze tracking system 202 can be stacked differently or manipulated in shape or size to minimize the size of the gaze-tracking system 202 to fit different x-, y-or z-dimensions.

Any of the features, components, and/or parts, including the arrangements and configurations thereof shown in FIG. 2A-2B can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 2A-2B.

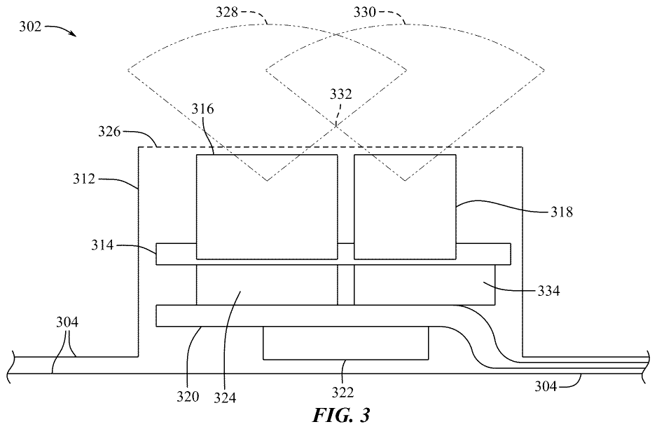

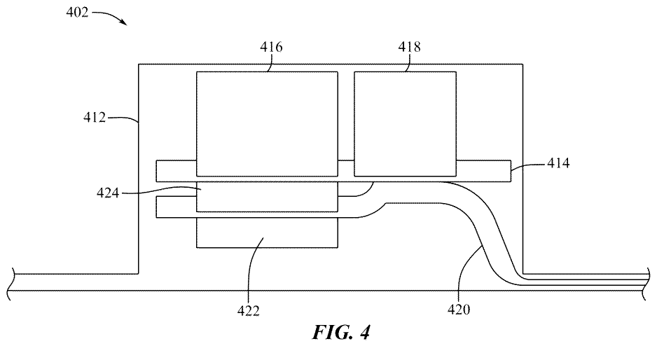

FIG. 3 shows an example of a cross-sectional view of a camera system 302. In some examples, the camera system 302 can be disposed in a wearable electronic display device, 100, 200, such as those shown in FIGS. 1 and 2A. In some examples, the camera system 302 can be substantially similar to, including some or all of the features of, the gaze tracking systems or camera systems described herein, such as gaze tracking system 202. In some examples, the camera system 302 can include an electronic flex 314, a camera 316, an illuminator 318, a stiffener 320, and a motion detector 322.

In some examples, the camera 316 can be coupled to the electronic flex 314 and can be configured to project a first light cone 328. In some examples, the camera can include an industry foundation classes (IFC) camera. In some examples, the camera can include an infrared camera. In some examples, the illuminator 318 can be coupled to the camera 316 via the electronic flex 314. In some examples, the illuminator can include a light emitting diode (LED). In some examples, the illuminator can include an infrared flood illuminator. In some examples, the illuminator 318 can project a second light cone 330. In some examples, the second light cone 330 and the first light cone 328 can define an intersection 332 where the second light cone 330 and the first light cone 328 first overlap. In some examples, the window 326 disposed in the housing 312 can be disposed between the intersection 332 and the camera 316 and/or the illuminator 318. In other examples, the intersection 332 can occur at the window 326. In some examples, if the intersection 332 occurs between the camera 316 and/or the illuminator 318 and the window 326, the intersecting light cones 328, 330 can create a reflection or other form of interference on the camera 316 and or the illuminator 318. This reflection or interference can cause the camera 316, illuminator 318, and/or other components of the camera system 302 to cease working or to work less effectively.

In some examples, a stiffener 320 can be coupled to the electronic flex 314 and the stiffener 420 can be cantilevered, clamped, tucked, or otherwise adhered into the structural frame 304 of the wearable electronic device, 100, 200. In some examples, portions of the stiffener 320, such as the portion coupled to the electronic flex 314 can be rigid or stiff. In some examples, portions of the stiffener 320 can be flexible, such as the portion of the stiffener 320 that bends into the structural frame 304 of the wearable electronic device 100, 200. In some examples, the stiffener 320 is just flexible enough to be bent and cantilevered into the structural frame 304. In these examples, the stiffener can be secured within the structural frame 304 in such a way that the camera system 302 is securely positioned in the housing 312 to prevent movement of the camera system 302 after its installment into the housing 312. This secure positioning can also allow very close placement of the camera 316 and illuminator 318 in the housing 312 to be very close to the window 326 without fear of damage to either the window 326 or the camera 316 or the illuminator 318 in a drop event or other event where a large amount of force is exerted on the camera system 302.

In some examples, a motion detector 322 can be coupled to at least one of the electronic flex 314 or the stiffener 320. In some examples, the motion detector 322 can be electrically coupled to at least one of the camera 316 or the illuminator 318. In some examples, the gaze tracking system can include additional components, for example it can include at least one of a shield can, an interposer 334, a processor, or other similar electrical components, 324. In some examples, these other electronic components, 324 such as a shield can or an interposer 334 can be electrically connected to at least one of the camera 316, the illuminator, 318, or the motion detector 322 either through direct or indirect coupling or via the electronic flex 314 and/or the stiffener 320.

Any of the features, components, and/or parts, including the arrangements and configurations thereof shown in FIG. 3 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 3.

FIG. 4 shows an example of a cross-sectional view of a camera system 402. In some examples, the camera system 402 can be disposed in a wearable electronic display device, 100, 200, such as those shown in FIGS. 1 and 2A. In some examples, the camera system 402 can be substantially similar to, including some or all of the features of, the gaze tracking systems or camera systems described herein, 202, 302. In some examples, the camera system 402 can be within a housing 412 and can include an electronic flex 414, a camera 416, an illuminator 418, a stiffener 420, and a motion detector 422. FIG. 4 shows an example of how the one or more other electrical components 424 can be coupled to both the stiffener 420 and the electronic flex 414. Although substantially similar, FIG. 4 mainly differs from FIG. 3 in showing only one other electrical component 424, rather than the two shown in FIGS. 3, 324, 334. These figures also highlight that the stiffener 420 and illuminator 418 can either be directly coupled, such as in FIG. 4 or indirectly coupled through electronic components, 324, 334 such as in FIG. 3. In some examples, such as that shown in FIG. 4, the stiffener 420 can have multiple flexible portions allowing it to bend into different configurations to couple to the multiple components within the camera system 402. In some examples, such as that shown in FIG. 4, the stiffener 420 can be directly coupled to the electronic flex 414 in some areas and indirectly coupled to the electronic flex 414 through an electronic component such as 424.

Any of the features, components, and/or parts, including the arrangements and configurations thereof shown in FIG. 4 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 4.

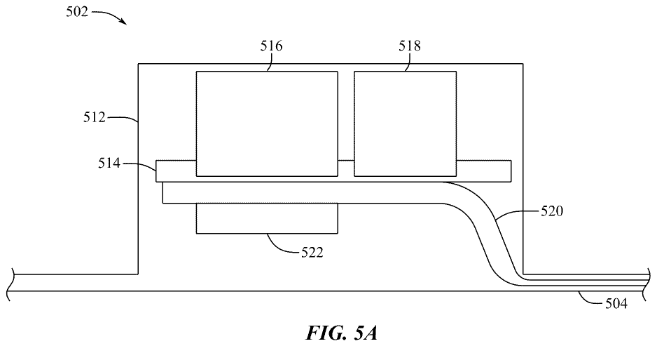

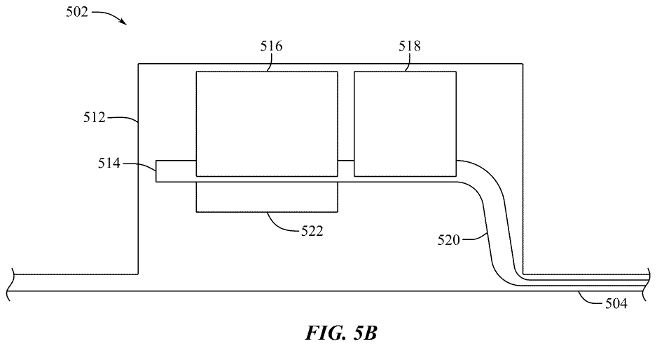

FIGS. 5A and 5B show examples of a cross-sectional view of a camera system 502. In some examples, the camera system 502 can be disposed in a wearable electronic display device, 100, 200, such as those shown in FIGS. 1 and 2A. In some examples, the camera system 502 can be substantially similar to, including some or all of the features of, the gaze tracking systems or camera systems described herein, 202, 302, 402. In some examples, the camera system 502 can include an electronic flex 514, a camera 516, an illuminator 518, a stiffener 520, and a motion detector 522. FIG. 5 shows an example without the one or more other electrical components 424. Additionally, FIG. 5A shows the electronic flex 514 directly coupled to the stiffener 520. FIG. 5B shows an alternative embodiment eliminating the electronic flex 514 and including the camera 516, the illuminator 518, and the motion detector 522 coupled directly to the stiffener 520. This embodiment can help to reduce the space required for the camera system 502, but it can be more flexible and thus susceptible to movement within the housing 512 despite the electronic flex being cantilevered into the structural frame 504.

Any of the features, components, and/or parts, including the arrangements and configurations thereof shown in FIG. 5A-5B can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 5A-5B.

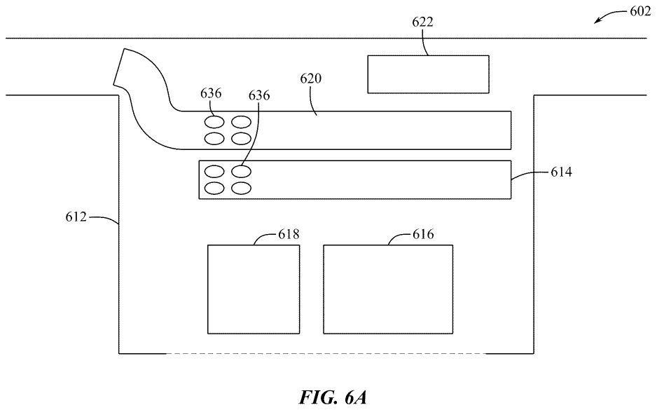

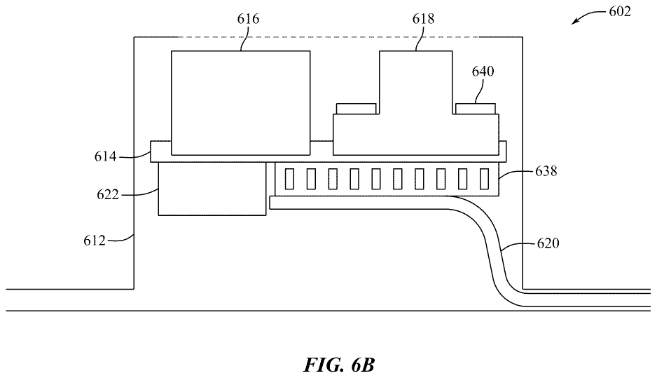

FIG. 6A-6B shows an example, the example exploded in FIG. 6A, of a cross-sectional view of the camera system 602. In some examples, the camera system 602 can be disposed in a wearable electronic display device, 100, 200, such as those shown in FIGS. 1 and 2A. The camera system 602 can be substantially similar to, including some or all of the features of the gaze tracking systems or camera systems described herein, 202, 302, 402, 502. The camera system 602 can include an electronic flex 614, a camera 616, an illuminator 618, a stiffener 620, and a motion detector 622. In some examples, the stiffener 620 can be bent to be positioned within the structural housing 612. In some examples, although the stiffener 620 is shown in FIG. 6 to stop after the bend in the stiffener 620, the stiffener 620 can extend throughout the structural housing 612 of the wearable electronic display device 100 and can electrically connect other electrical components within the wearable electronic display device.

In some examples, the electronic flex 614 can include a printed circuit board. The electronic flex 614 or printed circuit board can include a rigid printed circuit board. In some examples, the electrical coupling between the electronic flex 614 and the stiffener 620 can include at least one of a hot bar connection or a board-to-board connection. In the example shown in FIG. 6A, four hot bar connections 636 are shown. This is not limiting, and more or less hot bar connections can be included to electrically connect the electronic flex 614 and the stiffener 620. In some examples, the hot bar connections can also be included in different configurations or patterns on the electronic flex 614 and the stiffener 620, connecting specific portions of the electronic flex 614 and the stiffener 620, or connecting the length of the second side of the electronic flex 614b with the corresponding length of the stiffener 620.

In FIG. 6B, the electronic flex 614 and the stiffener 620 are shown electrically coupled via a board-to-board connection. In some examples, although the board-to-board connector 638 is shown to span the length of the electronic flex 614 and the stiffener 620, there may be one or more board-to-board connectors 638 connecting the electronic flex 614 and the stiffener 620 and the one or more board-to-board connectors 638 can span the length or only be included in particular portions of the electronic flex 614 or the stiffener 620. In some examples, the camera 616, illuminator 618, and the motion detector 622 can be electrically connected to at least one of the electronic flex 614 or the stiffener 620. camera 616, illuminator 618, and the motion detector 622 can also be electrically connected via hot bar connections 636 or board-to-board connectors 638 or pin connector. In some examples, such as the illuminator 618 shown in FIG. 6B, the illuminator 618 can include a light seal 640. The light seal 640 can block ambient light within the structural housing 612. In some examples, the light seal 640 can include foam surrounding the illuminator 618.

Any of the features, components, and/or parts, including the arrangements and configurations thereof shown in FIG. 6A-6B can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 6A-6B.

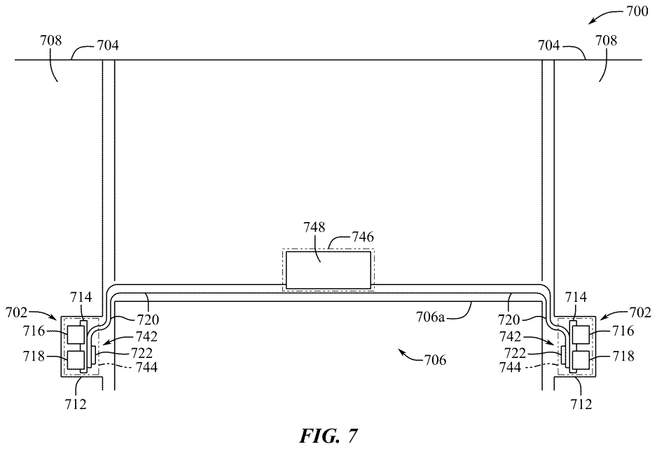

FIG. 7 shows an example of an enlarged view of a nosepiece 706 of a wearable electronic display device 700 with two inward facing camera systems 702. In some examples, the inward facing camera system 702 can be disposed in a wearable electronic display device, 700 similar to wearable electronic display devices 100, 200. In some examples, the inward facing camera system 702 can be substantially similar to, including some or all of the features of, the gaze tracking systems or camera systems described herein, 202, 302, 402, 502, 602. The example enlarged nosepiece 706 shown in FIG. 7 may not be at the correct scale as the nosepiece 706, the nose bridge 706a, the viewing frame 704, and the inward facing camera systems 702 can all vary in size and shape. Additionally, although two inward facing camera systems 702 are shown in FIG. 7, only one inward facing camera system 702 is contemplated. In some examples, more than two inward facing camera systems 702 are also contemplated.

In some examples, the nosepiece 706 can define a housing 712. In some examples, the housing can comprise a nose bridge 706a configured to rest on a nose of a user of the wearable electronic display device 700 when it is donned. In some examples, the housing 712 can further include an inward facing camera system 702. In some examples, the inward facing camera system 702 can be disposed in an internal cavity 742 of the housing 712. In some examples, the inward facing camera system 702 can include a first circuit 744, a camera 716, an illuminator 718, a second circuit 746, a flexible printed circuit 720 and a gyroscope 722. In some examples, the first circuit can have a printed circuit board (PCB) 8. In some examples, the camera 716 can be electrically coupled to the first circuit 744 via the PCB 714. In some examples, the illuminator 718 can be electrically coupled to the first circuit 744 via the PCB 714.

In some examples, the flexible printed circuit 720 can comprise a material that is flexible. “Flexible” components and materials described herein are those intended to deform, bend, change shape, deform, or otherwise be malleable as part of the component's intended function and/or without breaking or negatively affecting that function. For example, the flexible printed circuit 720 shown in FIG. 7 is shown bent in about a 90-degree angle in four different sections, however, this example is not meant to be limiting and the flexible printed circuit 720 can be bent at a greater or smaller angle and can be bent in more or less portions during manufacturing and/or assembly. In some examples, the flexible printed circuit 720 can have rigid portions along with flexible portions, for example the flat portion shown in FIG. 7 where the gyroscope 722 is coupled to the flexible printed circuit 720 can be an example of a rigid portion of the flexible printed circuit 720. Similarly, more or less rigid portions can be included in the flexible printed circuit 720 and the rigid portions are not required to be flat.

In some examples, the second circuit 746 can be disposed in the nose bridge 706a. In other examples, the second circuit 746 can be disposed in the housing 712 of the viewing frame 704 of the wearable electronic display device 700. In some examples, the flexible printed circuit 720 can be coupled to the PCB 714. In some examples, the flexible printed circuit 720 can electrically couple the first circuit 744 to the second circuit 746. In some examples, the gyroscope 722 can be coupled to the PCB 714 or the flexible printed circuit 720. In some examples, the gyroscope 722 can be electrically coupled to the first circuit 744. In some examples, the gyroscope 722 can be rigidly coupled to the camera 716. In some examples, the gyroscope 722 can be rigidly coupled to the camera 716 such that the gyroscope 722 can be used to calibrate the camera 716. In such an example, the rigid connection of the gyroscope 722 relative to the camera 716, including a fixed, immovable connection during normal use, can be a part of a movement sensor assembly or system for determining the movement of the camera 716 in all directions. For example, the gyroscope 722 must be rigidly coupled to the camera 716 to maintain the gyroscope's 722 orientation in inertial space and be unaffected by external movements of the wearable electronic display device 700. In some examples, an electronic component 748 can be included outside of the internal cavity 742 and be in any location within the structural frame 704 or disposed on the structural frame 704. In some examples, the electronic component 748 can be electrically connected to the second circuit 746 and electrically connected to the first circuit 744 and the components within the first circuit 744 (such as the camera 716, illuminator 718, gyroscope 722, and other electrical components not shown in the example shown in FIG. 7) via the flexible printed circuit 720. This can allow various electrical components electrically connected to the second circuit 746 and positioned anywhere on or within the wearable electronic display device, such as within or disposed on the viewing frame 704 or the display 708, to be electrically connected with the components within the first circuit 744 such as one or more of the camera 716, illuminator 718, the gyroscope 722 or other electrical components not shown in FIG. 7.

Any of the features, components, and/or parts, including the arrangements and configurations thereof shown in FIG. 7 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 7.

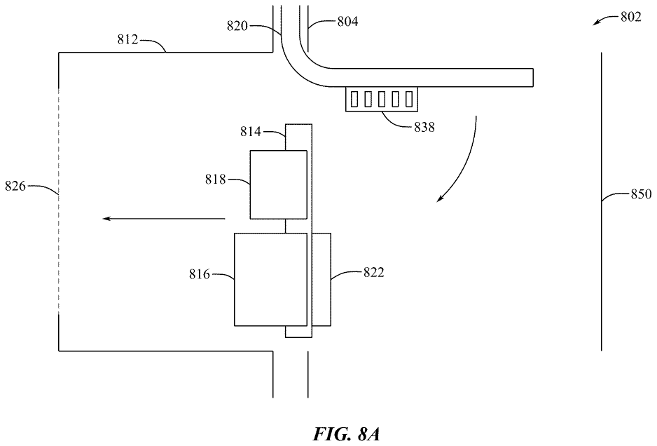

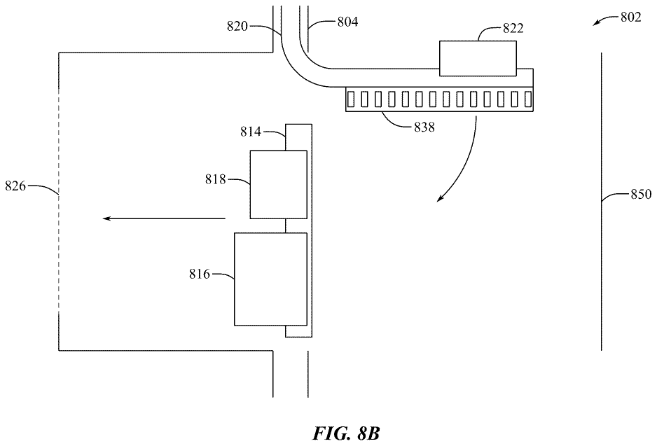

FIGS. 8A and 8B show examples of a method of installing a gaze tracking system 802 within a wearable electronic display device. In some examples, the gaze tracking system 802 can be disposed in a wearable electronic display device, 100, 200, 700 such as those shown in FIGS. 1, 2A or 7. The gaze tracking system 802 can be substantially similar to, including some or all of the features of, the gaze tracking systems or camera systems described herein, 202, 302, 402, 502, 602, 702. FIG. 8A shows an example of a method of installing a gaze tracking system 802 by positioning a pre-assembled PCB 814 with the camera 816 and the illuminator 818 into the housing 812 of the wearable electronic device 100. Alternatively, one or more of the camera 816 or illuminator 818 can be coupled to the PCB 814 within the housing. The example in FIG. 8A shows the gyroscope 822 coupled also coupled to the PCB 814. As seen and described in other figures and other parts of the specification, this is only one position the gyroscope can be placed in and is not meant to be limiting. As shown in the example shown in FIG. 8B, the gyroscope can also or alternatively be coupled to the flexible printed circuit 820. In some examples, the gyroscope can be pre-assembled to be coupled to one or more of the PCB 714 or the flexible printed circuit 820. In other examples, the gyroscope can be coupled to one or both of PCB 814 and flexible printed circuit 820 during assembly of the gaze tracking system 802. Although not shown, in some examples, other electrical components can be pre-assembled or added to the gaze tracking system 802 via the PCB 814 or the flexible printed circuit 820.

In some examples, the flexible printed circuit 820 can be cantilevered into the viewing frame 804 of the wearable electronic display device 700. In some examples, the flexible printed circuit 820 can be flexible enough to bend into different configurations, allowing for the PCB 814 with other components pre-installed to be placed nearest the window 826 disposed in the housing 812. In some examples, the flexible printed circuit 820 can be bent out of the way to allow for installation of one or more of the camera 816, illuminator 818, gyroscope 822, or PCB 814 within the housing 812. In some examples, once the camera 816, illuminator 818, the PCB 814, and optionally the gyroscope 822 (depending on the desired position of the gyroscope 822) are in place positioning the camera 816 and the illuminator 818 near the window 826, the flexible printed circuit 820 can be positioned within the housing 812.

In some examples, the flexible printed circuit 820 can be pre-installed with other components, such as the gyroscope 822, for example a gyroscope, as shown in FIG. 8B. In other examples, electronic components, such as the gyroscope 822 can be coupled to the flexible printed circuit 820 during installation of the gaze tracking system 802 before it is bent back in place or after it is positioned in place. In some examples, once the flexible printed circuit 820 is positioned in place and electrically coupled to the PCB 714, a rear wall 850 of the housing 812 can be placed through various means such as with a liquid adhesive, welding, soldering, machining, or other similar methods.

Both FIG. 8A and FIG. 8B show examples of the PCB 814 and the flexible printed circuit 820 being electrically coupled via a board-to-board connection 838. However, other methods of electrical connections such as hot bar and other similar means of electrically connecting printed circuit boards are also contemplated. As discussed above, in some examples, the electrical connection can cover most of the length of the PCB 814, as shown in FIG. 8B, or electrical connections can cover only certain sections of the PCB 814 and the flexible printed circuit 820, as shown in FIG. 8A. In some examples, the connection between the PCB 814 and the flexible printed circuit 820 can either be direct, as shown in FIG. 8B, direct in part, as shown in FIG. 8A, can be indirect, or can be indirect in part through the connection of one or more electrical components such as the gyroscope 822, also shown in FIG. 8A.

Only the open configurations with the flexible printed circuit 820 bent out of the way to position the camera 716, illuminator 818, the PCB 714, and optionally the gyroscope 822 or other electronic components is shown in FIG. 8A-8B. However, examples of various embodiments of closed and completed gaze tracking system 802 within wearable electronic display devices after installation of the gaze tracking system 802 are shown in FIG. 2B-5B and 6B-7.

Any of the features, components, and/or parts, including the arrangements and configurations thereof shown in FIG. 8A-8B can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 8A-8B.

To the extent applicable to the present technology, gathering and use of data available from various sources can be used to improve the delivery to users of invitational content or any other content that may be of interest to them. The present disclosure contemplates that in some instances, this gathered data may include personal information data that uniquely identifies or can be used to contact or locate a specific person. Such personal information data can include demographic data, location-based data, telephone numbers, email addresses, X® (formerly TWITTER®) ID's, home addresses, data or records relating to a user's health or level of fitness (e.g., vital signs measurements, medication information, exercise information), date of birth, or any other identifying or personal information.

The present disclosure recognizes that the use of such personal information data, in the present technology, can be used to the benefit of users. For example, the personal information data can be used to deliver targeted content that is of greater interest to the user. Accordingly, use of such personal information data enables users to calculated control of the delivered content. Further, other uses for personal information data that benefit the user are also contemplated by the present disclosure. For instance, health and fitness data may be used to provide insights into a user's general wellness or may be used as positive feedback to individuals using technology to pursue wellness goals.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the US, collection of or access to certain health data may be governed by federal and/or state laws, such as the Health Insurance Portability and Accountability Act (HIPAA); whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, in the case of advertisement delivery services, the present technology can be configured to allow users to select to “opt in” or “opt out” of participation in the collection of personal information data during registration for services or anytime thereafter. In another example, users can select not to provide mood-associated data for targeted content delivery services. In yet another example, users can select to limit the length of time mood-associated data is maintained or entirely prohibit the development of a baseline mood profile. In addition to providing “opt in” and “opt out” options, the present disclosure contemplates providing notifications relating to the access or use of personal information. For instance, a user may be notified upon downloading an app that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data a city level rather than at an address level), controlling how data is stored (e.g., aggregating data across users), and/or other methods.

Therefore, although the present disclosure broadly covers use of personal information data to implement one or more various disclosed embodiments, the present disclosure also contemplates that the various embodiments can also be implemented without the need for accessing such personal information data. That is, the various embodiments of the present technology are not rendered inoperable due to the lack of all or a portion of such personal information data. For example, content can be selected and delivered to users by inferring preferences based on non-personal information data or a bare minimum amount of personal information, such as the content being requested by the device associated with a user, other non-personal information available to the content delivery services, or publicly available information.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not intended to be exhaustive or to limit the embodiments to the precise forms disclosed. It will be apparent to one of ordinary skill in the art that many modifications and variations are possible in view of the above teachings.

What is claimed is:

1. A wearable electronic display device, comprising:
a structural frame including a nosepiece, the nosepiece comprising:
a housing;
a gaze tracking system disposed in the housing and comprising:
a printed circuit board including a first side and a second side opposite the first side;
a camera coupled to the first side;
an illuminator coupled to the first side and electrically coupled to the camera;
a flexible circuit electrically coupled to the second side; and
a motion sensor coupled to the second side or to the flexible circuit, wherein the motion sensor is electrically coupled to the camera and the illuminator.

2. The wearable electronic display device of claim 1, wherein:
the camera comprises a radial angle of view;
the illuminator comprises a radial angle of illumination;
the radial angle of view and the radial angle of illumination define an intersection; and
the housing is disposed between the illuminator and the intersection.

3. The wearable electronic display device of claim 1, further comprising an interposer electrically connected to the camera.

4. The wearable electronic display device of claim 3, wherein the interposer is coupled to the second side or to the flexible circuit.

5. The wearable electronic display device of claim 1, wherein the gaze tracking system further comprises a shield can coupled to the first side, to the second side, or to the flexible circuit.

6. The wearable electronic display device of claim 1, wherein the illuminator comprises an electromagnetic interference shield.

7. The wearable electronic display device of claim 1, wherein the illuminator comprises a light seal.

8. The wearable electronic display device of claim 1, wherein the flexible circuit is electrically coupled to the second side through at least one of a hot bar connection or a board-to-board connection.

9. The wearable electronic display device of claim 1, wherein the printed circuit board comprises a rigid printed circuit board.

10. The wearable electronic display device of claim 1, wherein:
the nosepiece further comprises an internal cavity positioned adjacent to the housing; and
the flexible circuit is cantilevered into the internal cavity.

11. A wearable electronic display device, comprising:
a structural frame defining a housing, the housing comprising:
a window; and
a camera system disposed in the housing, the camera system comprising:
an electronic flex;
a camera coupled to the electronic flex and configured to project a first light cone;
an illuminator coupled to the camera via the electronic flex and configured to project a second light cone, wherein the second light cone and the first light cone define an intersection, and the window is disposed between the camera and the intersection;
a stiffener coupled to the electronic flex and cantilevered into the structural frame; and
a motion detector coupled to at least one of the electronic flex or the stiffener, wherein the motion detector is electrically coupled to the camera and the illuminator.

12. The wearable electronic display device of claim 11, wherein the camera system comprises a thickness of less than 5 millimeters.

13. The wearable electronic display device of claim 11, wherein the camera system comprises a thickness of less than 3 millimeters.

14. The wearable electronic display device of claim 11, wherein the illuminator comprises a light-emitting diode.

15. The wearable electronic display device of claim 11, wherein the illuminator comprises an infrared flood illuminator.

16. A viewing frame of a wearable electronic display device, comprising:
a nosepiece defining a housing, the nosepiece comprising:
a nose bridge configured to rest on a nose of a user; and
an inward facing camera system disposed in an internal cavity of the housing, the inward facing camera system comprising:
a first circuit having a printed circuit board (PCB);
a camera electrically coupled to the first circuit via the PCB;
an illuminator electrically coupled to the first circuit via the PCB;
a second circuit disposed in the nose bridge;
a flexible printed circuit coupled to the PCB and electrically coupling the first circuit to the second circuit; and
a gyroscope coupled to the PCB or the flexible printed circuit and electrically coupled to the first circuit.

17. The viewing frame of a wearable electronic display device of claim 16, wherein the gyroscope comprises a pin connector configured to couple to at least one of the PCB or the flexible printed circuit.

18. The viewing frame of a wearable electronic display device of claim 16, wherein the gyroscope is rigidly coupled to the camera.

19. The viewing frame of a wearable electronic display device of claim 16, wherein the gyroscope is positioned in line with at least one of the camera or the illuminator.

20. The viewing frame of a wearable electronic display device of claim 16, wherein:
the gyroscope is positioned between the nose bridge and both the camera and the illuminator; or
the camera and the illuminator are positioned between the gyroscope and the nose bridge.
